(19) United States
(12) Patent Application Publication
(10) Pub. No.: US 2026/0280415 A1
(43) Pub. Date: Sep. 17, 2026

(54) DEVICE FOR MONITORING A POWER SUPPLY

(71) Applicant: Phoenix Contact GmbH & Co. KG, Blomberg (DE)

(72) Inventors: Lars ALSDORF, Soest (DE); Jochen ZEUCH, Blomberg (DE); Alexander Haneke, Geseke (DE)

(21) Appl. No.: 18/877,280

(22) PCT Filed: Jun. 30, 2023
(86) PCT No.: PCT/EP2023/067967

§ 371 Date: Dec. 20, 2024

(30) Foreign Application Priority Data
Jul. 1, 2022 (BE) BE2022/5541

(51) Int. Cl. H02M 1/32; G01R 19/165; G01R 31/40; H02M 1/08; H02M 3/335

(52) U.S. Cl. CPC H02M 1/32; G01R 19/16538; G01R 31/40; H02M 1/08; H02M 3/33507; H02M 3/33561

(57) ABSTRACT

A device for monitoring a power supply for Safety Extra Low Voltage includes: a first monitoring element for monitoring a first current, I1, and a first voltage, U1, which are output on a secondary side of a voltage converter; a primary side control element signal conducting connected to the first monitoring element for controlling the voltage converter on a primary side based on the first current, I1, and the first voltage, U1, when a first threshold value is exceeded; and a second monitoring element for monitoring a second current, I2, and a second voltage, U 2, the second current, I2, and the second voltage, U2, being based on the first current, I1, and the first voltage, U1, with the second monitoring element supplied by the first monitoring element with the first current, I1, and the first voltage, U1. The primary side control element is signal conducting.

### CROSS-REFERENCE TO PRIOR APPLICATIONS

This application is a U.S. National Phase application under 35 U.S.C. § 371 of International Application No. PCT/EP2023/067967, filed on Jun. 30, 2023, and claims benefit to Belgian Patent Application No. BE2022/5541, filed on Jul. 1, 2022. The International Application was published in German on Jan. 4, 2024 as WO/2024/003335 under PCT Article 21(2).

### FIELD

The invention relates to a technique for monitoring a power supply. Without being limited thereto, it pertains particularly to a device for monitoring a power supply for Safety Extra Low Voltage (SELV), where the extractable output power is increased relative to the maximum possible output power. For this purpose, the voltage and current regulation or limitation is redundantly implemented with two series-connected limiters.

### BACKGROUND

In power supplies for Safety Extra Low Voltage, also known technically as SELV, direct current (DC) up to 60 volts is provided. For instance, when providing 12 volts or 24 volts DC, to enhance safety, the output power is limited according to UL 1310 (Underwriters Laboratories) to consistently less than 100 watts. Furthermore, the associated limitation mechanisms, such as voltage, current, and power limitation, must be implemented in a fault-tolerant redundant manner, i.e., doubled. Systems oriented towards safety also require heightened protection against overvoltage and overcurrent. It is considered that the highest voltage in a power supply system determines the system voltage, and components may only operate safely up to a maximum voltage limit. Exceeding a current limit may cause a failure in a consumer connected to the system.

This redundant power limitation is achieved using small power supplies known in the prior art, whose power throughput is significantly below 100 watts. The first power limitation comprises of the natural power limitation of a power supply, which results from the maximum power limitation of the transformer. The second current limitation comprises of the usual built-in current limitation, for example, in the form of a fuse, e.g. as a melting fuse. Both mechanisms limit the maximum power in a single-fault-tolerant manner to a certain upper limit.

However, this requires a significant margin from the maximum possible output power due to considerable inaccuracy of the limitations. Additionally, downstream fuses at an output of a power supply require a significant safety margin, as they allow a considerably higher current for a certain time than the nominal value of the fuse, which also strongly depends on the ambient temperature. In summary, these methods usually allow a limitation to a maximum of two-thirds of the possible output power.

### SUMMARY

In an embodiment, the present invention provides a device for monitoring a power supply for Safety Extra Low Voltage, comprising: a first monitoring element configured to monitor a first current, I1, and a first voltage, U1, which are output on a secondary side of a voltage converter; a primary side control element signal conducting connected to the first monitoring element and configured to control the voltage converter on a primary side based on the first current, I1, and the first voltage, U1, when a first threshold value is exceeded; and a second monitoring element configured to monitor a second current, I2, and a second voltage, U2, the second current, I2, and the second voltage, U2, being based on the first current, I1, and the first voltage, U1, with the second monitoring element supplied by the first monitoring element with the first current, I1, and the first voltage, U1, wherein the primary side control element is signal conducting connected to the second monitoring element and configured to control the voltage converter on the primary side based on the second current, I2, and the second voltage, U2, when a second threshold value is exceeded.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 a schematic block representation of a power supply with a device for its monitoring according to a first embodiment,

FIG. 2 a power supply with a device for its monitoring according to a second embodiment,

FIG. 3 a power supply with a device for its monitoring with a first monitoring element, a second monitoring element, and a second output unit according to a third embodiment,

FIG. 4 a power supply with a device for its monitoring with a first output unit and a second output unit according to a fourth embodiment, and

FIG. 5 a method for monitoring a power supply for Safety Extra Low Voltage.

### DETAILED DESCRIPTION

In an embodiment, the present invention provides a technique to reduce the gap between system power and the maximum possible output power in a power supply for Safety Extra Low Voltage while maintaining the required safety conditions. This allows for increased utilization of the power supply, leading to reduced costs.

Embodiments of the invention, which may be optionally combined with each other, are disclosed below with partial reference to the figures.

A first aspect concerns a device for monitoring a power supply for Safety Extra Low Voltage. The device comprises a first monitoring element configured to monitor a first current I1 and a first voltage U1, which are output on the secondary side of a voltage converter. Furthermore, the device comprises a primary side control element, which is signal conducting connected to the first monitoring element and configured to control the voltage converter on the primary side based on the first current I1 and the first voltage U1. The control is initiated at least when a first threshold value is exceeded. The device also comprises a second monitoring element configured to monitor a second current I2 and a second voltage U2, based on the first current I1 and the first voltage U1. The second monitoring element is supplied by the first monitoring element with the first current I1 and the first voltage U1. The primary side control element is signal conducting connected to the second monitoring element and configured to control the voltage converter on the primary side based on the second current I2 and the second voltage U2, when a second threshold value is exceeded.

Advantageously, embodiments may consider fault-tolerant redundant voltage and current limitations or voltage and power limitations or current and power limitations through double feedback to the primary side of the power supply, thereby improving regulation on the primary side. In particular, such regulation on the primary side may better achieve adherence to the required limits or achieve a total shutdown of the power supply if regulation is not successful or possible otherwise (e.g., through limitations of current, voltage, or power, or through selective shutdown of individual output units, i.e., output channels).

Preferably, the first threshold value may comprise a first current upper limit I1′, a first voltage upper limit U1′, or a first power upper limit P1′. Exceeding the first threshold value may occur by exceeding the first current upper limit I1′ alone. Additionally or alternatively, it may occur by exceeding the first voltage upper limit U1′ alone. Further, it may occur by exceeding the first power upper limit P1′ alone.

Alternatively or additionally, the second threshold value may comprise a second current upper limit I2′, a second voltage upper limit U2′, or a second power upper limit P2′. Exceeding the second threshold value may occur by exceeding the second current upper limit I2′ alone. Additionally or alternatively, it may occur by exceeding the second voltage upper limit U2′ alone. Further, it may occur by exceeding the second power upper limit P2′ alone.

The first current upper limit I1′ may be equal to or greater than the second current upper limit I2′. Alternatively or additionally, the first voltage upper limit U1′ may be equal to or greater than the second voltage upper limit U2′. Alternatively or additionally, the first power upper limit P1′ may be equal to or greater than the second power upper limit P2′.

Advantageously, a variety of threshold value exceedances may be used to control the voltage converter, which may monitor both the current, the voltage, and their product, the power. Further advantageously, additional output units with monitoring may be connected in parallel to the output units with the second monitoring element due to the increased current, voltage, and power values compared to the second monitoring element.

The device for monitoring the power supply may comprise a first output unit. This may provide the second current I2 and the second voltage U2 at a first supply output. The supply output of the output unit may be identical to the supply output of the power supply. The supply output may serve to electrically supply consumers, such as sensors or the like, that perform a monitoring function. For safe operation of the consumers, it is necessary not to exceed a maximum current, maximum voltage, and/or maximum power. The first output unit may comprise the second monitoring element.

Advantageously, the provided current, voltage, and power at the output of the power supply may thus be comprised in the regulation. Further advantageously, component formation may be simplified or a modular design enabled by forming a combination of output unit and monitoring element as interchangeable and/or supplementary components.

Furthermore, the first output unit may comprise a first switch for shutting off the first supply output. This switch may be controlled by the second monitoring element. The second monitoring element may monitor the second threshold value. This may comprise monitoring the second current upper limit I2, the second voltage upper limit U2, and/or the second power upper limit P2. Alternatively, upper limits of current I1′, voltage U1′, and power P1′ may be monitored, which are based on the second current upper limit I2, the second voltage upper limit U2, and/or the second power upper limit P2.

Advantageously, a local overload condition in the form of a first threshold value exceedance may thus be addressed in the first output unit, for example, with lower upper limits.

Moreover, a second output unit, which provides a third current I3 and a third voltage U3 at a second supply output, may be arranged and electrically connected in the device for monitoring the power supply. The second output unit may be supplied by the first monitoring element with the first current I1 and the first voltage U1. The second output unit may be arranged in parallel to the first output unit and/or connected in parallel with respect to the first voltage U1. The second output unit may differ from the first output unit regarding the type and scope of monitoring as well as the amount of monitored upper limits of current, voltage, and/or power.

Advantageously, a plurality of currents I2, I3, voltages U2, U3, and powers P2, P3 may thus be monitored, wherein the currents and voltages may differ from each other. Further advantageously, different monitoring mechanisms may be deployed through the different configuration of the output units.

Furthermore, in the device for monitoring the power supply, the second output unit may comprise a second switch for shutting off the second supply output. The second output unit may monitor a third threshold value. This may comprise monitoring the third current upper limit I3, the third voltage upper limit U3, and/or a third power upper limit P3. Alternatively, upper limits of current I3′, voltage U3′, and power P3′, which are based on the third current upper limit I3, the third voltage upper limit U3, and/or the third power upper limit P3, may be monitored.

Advantageously, a local overload condition in the second output unit may thus be addressed in the form of a first threshold value exceedance. Further advantageously, the second output unit may be executed more cost-effectively by eliminating signaling to the primary side control element.

Further, in the device, the first switch may be operated depending on an exceedance of the second threshold value. The second switch may be operated depending on an exceedance of a third threshold value. Alternatively or additionally, signaling of the second threshold value may be based on a malfunction of the first switch. Alternatively or additionally, signaling of the third threshold value may be based on a malfunction of the second switch.

Advantageously, a differentiated switch operation and thus shutdown of the respective electrical supply may be achieved depending on the exceedance of the respective threshold values.

Furthermore, separation of the second switch may be based on internal signals of the second output unit. Alternatively or additionally, separation of the first switch may be based on internal signals of the first output unit.

Optionally, with the shutdown of the first switch, the exceedance of the first threshold value may also be signaled to the primary side control element. Further optionally, a malfunction of the first switch may be signaled to the primary side control element. This may comprise signaling in case of failure to open the switch. The signaling options to be activated may be preset in the device.

Further optionally, signaling to the primary side control element may be omitted if the third threshold value is exceeded. Alternatively, with the shutdown of the second switch, the exceedance of the third threshold value may also be signaled to the primary side control element. Further optionally, a malfunction of the second switch may be signaled to the primary side control element. This may comprise signaling in case of failure to open the switch. The signaling options to be activated may be preset in the device.

Advantageously, reactions to threshold value exceedances or malfunctions in the output units may be flexible (e.g., selectively for individual output units) and/or preset, both locally in the output units and in connection with the primary side.

Furthermore, the device may comprise a primary side arranged switching element, which is arranged between the primary side control element and the voltage converter and electrically connected with it. The primary side arranged switching element may control the voltage converter on the primary side based on signals from the primary side control element. This control influences the first current I1 and the first voltage U1. Alternatively, this control causes the shutdown of the first current I1 and the shutdown of the first voltage U1.

Advantageously, central control of the voltage converter may thus occur.

In each variant mentioned herein, the signal conducting connection with the primary side control element may comprise an inductive and/or capacitive and/or optical coupling element. Optionally, the signal conducting connection with the first monitoring element may comprise a first coupling element and the signal conducting connection with the second monitoring element may comprise a second coupling element (which is different from the first coupling element). The first coupling element may also comprise the signal conducting connection with the second output unit. The coupling elements may be arranged in parallel. The coupling elements may use the same or different technologies (inductive, capacitive, optical). Alternatively, each signal conducting connection may comprise its own coupling element, wherein the coupling elements may optionally be arranged in parallel. The coupling elements may galvanically isolate the secondary side from the primary side of the power supply.

Advantageously, the fault redundancy in threshold value monitoring may be increased while simultaneously galvanically isolating the secondary side and primary side of the power supply.

Furthermore, the monitoring elements of the device for monitoring the power supply may be configured to monitor an exceedance of the threshold values as well as the duration of the threshold value exceedance. Signaling of the threshold value exceedance may only take place after the expiration of the predetermined duration. The value of an exceedance threshold value may be multiple times the threshold value, for example, 2 to 10 times the threshold value. Furthermore, the duration of the threshold value exceedance may be 2 to 5 seconds. The exceedance threshold value and the duration of the threshold value exceedance may be preset in the device.

Advantageously, monitoring may thus be individually adapted to the connected consumers, which may also comprise the operation and particularly the startup of motors.

Moreover, in the device for monitoring the power supply, the threshold values may be adjustable by a user. The settings may also be made from a remote (e.g., spatially or network topologically separated) station and received via an interface. Alternatively or additionally, the settings of the threshold values may each comprise an adjustable duration of the allowed threshold value exceedance.

Advantageously, an effective adaptation to the connected consumers may thus be achieved.

Further, a power supply for Safety Extra Low Voltage may comprise the device for monitoring the power supply. The power supply may meet the Safety Extra Low Voltage requirements, SELV. Furthermore, it may also comply with the UL 1310 regulations.

Advantageously, simpler wiring (e.g., with less wire cross-section) of the connected consumers may be used. Further advantageously, connecting the consumers may also be performed by less qualified personnel.

Moreover, the voltage converter of the power supply may comprise a transformer, a switch mode power supply, a forward or flyback converter, or a resonant converter.

Advantageously, various demands on the power supply may thus be met regarding cost, stability of current, voltage and power, and/or space.

A second aspect concerns a method for monitoring a power supply for Safety Extra Low Voltage. The method comprises monitoring, with a first monitoring element, a first current I1 and a first voltage U1, which are output on the secondary side of a voltage converter. The method further comprises primary side controlling of the voltage converter with a primary side control element, which is signal conducting connected to the first monitoring element, based on the first current I1 and the first voltage U1, when a first threshold value is exceeded. The method further comprises monitoring with a second monitoring element, a second current I2 and a second voltage U2, wherein the second current I2 and the second voltage U2 are based on the first current I1 and the first voltage U1. The second monitoring element is supplied by the first monitoring element with the first current I1 and the first voltage U1. Furthermore, the method comprises primary side controlling of the voltage converter based on the second current I2 and the second voltage U2, when a second threshold value is exceeded, wherein the primary side control element is signal conducting connected to the second monitoring element.

Subsequently, the invention is explained in more detail with reference to the attached drawings based on preferred embodiments, which may be optionally combined.

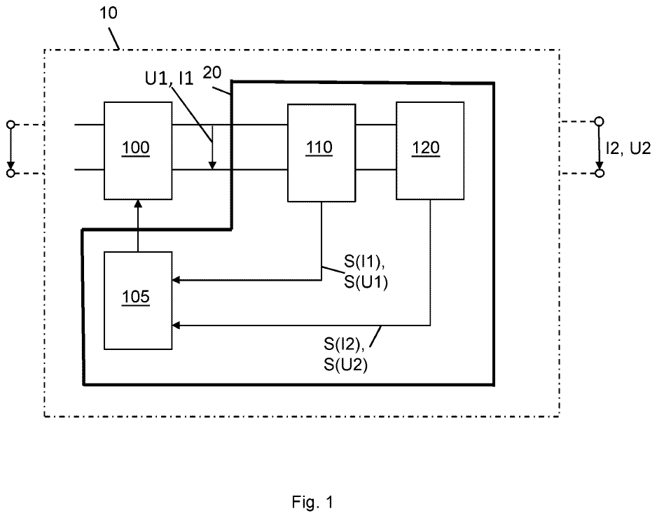

FIG. 1 shows a schematic block representation of a power supply 10 with a device 20 for its monitoring. The device 20 serves for monitoring a power supply 10 for Safety Extra Low Voltage. The power supply 10 comprises input terminals, at which a usual supply voltage of 230 volts or 120 volts AC is applied. Furthermore, the power supply comprises at least one pair of output terminals, at which an output voltage U2 is present and an output current I2 is available.

The device 20 comprises a first monitoring element 110 configured to monitor a first current I1 and a first voltage U1, which are output on the secondary side of a voltage converter 100. For this purpose, the device 20 is electrically connected to the voltage converter 100. Furthermore, the device 20 comprises a primary side control element 105, which is signal conducting connected to the first monitoring element 110 and configured to control the voltage converter 100 on the primary side based on the first current I1 and the first voltage U1, when a first threshold value is exceeded. For this purpose, a signal corresponding to the first current S(I1) and a signal corresponding to the first voltage S(U1) are generated in the first monitoring element 110 and supplied to the primary side control element 105. Additionally, the device 20 comprises a second monitoring element 120 configured to monitor a second current I2 and a second voltage U2, wherein the second current I2 and the second voltage U2 are based on the first current I1 and the first voltage U1. The second monitoring element 120 is supplied by the first monitoring element 110 with the first current I1 and the first voltage U1. Moreover, the primary side control element 105 is signal conducting connected to the second monitoring element 120 and configured to control the voltage converter 100 on the primary side based on the second current I2 and the second voltage U2, when a second threshold value is exceeded. For this purpose, a signal corresponding to the second current S(I2) and a signal corresponding to the second voltage S(U2) are generated in the second monitoring element 120 and supplied to the primary side control element 105. Accordingly, the first monitoring element 110 and the second monitoring element 120 are arranged on the secondary side of the power supply, while the primary side control element 105 is arranged on the primary side, as the term already suggests.

The SELV power supply 10 is designed for Safety Extra Low Voltage in accordance with UL 1310 (Class II Power Unit). The voltage converter 100 of the power supply 10 is galvanically isolating or alternatively non-galvanically isolating. The voltage converter 100 is a transformer, a switch mode power supply, a forward or flyback converter, or a resonant converter, which is designed, for example, as an LLC converter. The LLC converter (two inductors, one capacitor) is a resonant converter with three reactive elements.

The first threshold value comprises several measurement quantities, which comprise a first current upper limit I1′ and a first voltage upper limit U1′ or a first power upper limit P1′. Accordingly, measurement limit pairs may comprise of the first current upper limit I1′ and the first voltage upper limit U1′ or of the first current upper limit I1′ and the first power upper limit P1′. Additionally or alternatively, a measurement limit pair may comprise of the first voltage upper limit U1′ and the first power upper limit P1′.

The second threshold value comprises several measurement quantities, which comprise a second current upper limit I2′ and a second voltage upper limit U2′ or a second power upper limit P2′. Accordingly, measurement limit pairs may comprise of the second current upper limit I2′ and the second voltage upper limit U2′ or of the second current upper limit I2′ and the second power upper limit P2′. Additionally or alternatively, a measurement limit pair may comprise of the second voltage upper limit U2′ and the second power upper limit P2′.

The first current upper limit I1′ is equal to or greater than the second current upper limit I2′. The first voltage upper limit U1′ is equal to or greater than the second voltage upper limit U2′. The first power upper limit P1′ is equal to or greater than the second power upper limit P2′.

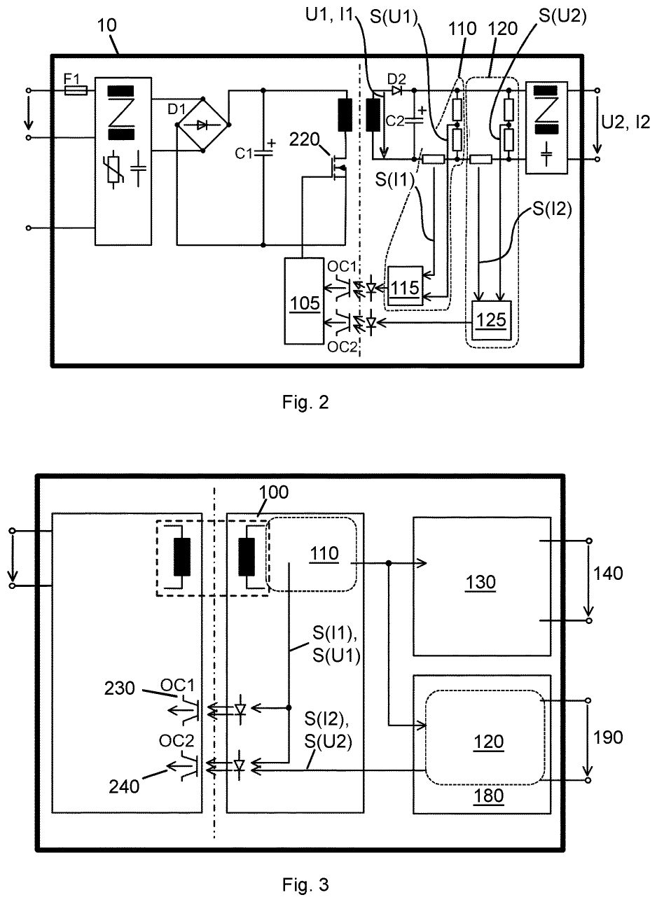

FIG. 2 shows the power supply 10 with the device 20 for its monitoring. The device 20 comprises a first monitoring element 110 and a second monitoring element 120. The first monitoring element 110 itself comprises a voltage divider, which derives the signal S(U1) from the voltage U1. Furthermore, the first monitoring element 110 comprises a current measuring device, which is implemented as a shunt resistor. This derives the signal S(I1) from the current I1. The signals S(U1) and S(I1) are supplied to the first comparator 115, which checks the individual threshold values of the upper limits for current I1′, voltage U1′, and power P1′. Upon exceeding at least one individual threshold value, the first comparator 115 signals the exceedance of the respective upper limit to the primary side control element 105. The signaling may also comprise the amount of exceedance and information about the course of exceedance. In particular, the exceedance may be signaled only after a certain time has elapsed, as will be detailed later.

The second monitoring element 120 itself comprises a voltage divider, which derives the signal S(U2) from the voltage U2. Furthermore, the second monitoring element 120 comprises a current measuring device, which is implemented as a shunt resistor. This derives the signal S(I2) from the current I2. The signals S(U2) and S(I2) are supplied to the second comparator 125, which checks the individual threshold values of the upper limits for current I2′, voltage U2′, and power P2′. Upon exceeding at least one individual threshold value, the second comparator 125 signals the exceedance of the respective upper limit to the primary side control element 105. As with the first comparator 115, the second comparator 125 may comprise the amount of exceedance and information about the course of exceedance in addition to signaling. In particular, the exceedance may be signaled only after a certain time has elapsed, as will be detailed later.

The power supply 10 together with the device 20 comprises a primary side fuse F1, which is arranged on an input line of two input lines from two input terminals. It further comprises an electromagnetic compatibility (EMC) filter (without reference number), which is arranged between the two input lines. It also comprises a rectifier circuit D1, which terminates the two input lines. It further comprises a capacitor C1 for smoothing the input voltage, which is connected to the two output lines of the rectifier circuit D1. Furthermore, the device 20 comprises the partial voltage converter 100 of the primary side, which is connected to the capacitor C1. Finally, the device 20 comprises the control element 105 and the associated switching element 220 for primary side switching of the voltage converter 100. The control element 105 is further connected to the primary side portions of the optocouplers OC1 and OC2.

On the secondary side, the power supply 10 together with the device 20 comprises the partial voltage converter 100 of the secondary side, a diode D2 in one of the two lines of the secondary side voltage converter 100, and a capacitor C2, which is arranged between the lines of the secondary side voltage converter 100. Furthermore, the secondary side comprises an EMC filter (without reference number) at the output of the power supply U2/I2. Finally, the secondary side comprises the secondary side portions of the optocouplers OC1 and OC2, which are connected with the comparators/regulation 115 or 125. On the primary side, the two optocouplers OC1 and OC2 control the circuit breaker 220 through an appropriate implementation 105, e.g., by pulse width modulation or pulse frequency modulation.

FIG. 3 shows the power supply 10 with a device 20 for its monitoring, with the voltage converter 100, a first monitoring element 110, a second monitoring element 120, and a second output unit 130. The power supply 10 with the device 20 comprises a first output unit 180, which provides the second current I2 and the second voltage U2 at a first supply output 190. The first output unit 180 comprises the second monitoring element 120. The second output unit 130 comprises a second supply output 140, which provides a third current I3 and a third voltage U3. The first monitoring element 110 is connected to the optocoupler OC1 230. It may additionally be connected to the optocoupler OC2. The first monitoring element 110 signals the signals S(I1) and S(U1). The second monitoring element 120 is connected to the optocoupler OC2 240. The second monitoring element 120 signals the signals S(I2) and S(U2). The first output unit 180 and the second output unit 130 are fed by the first monitoring element 110 with the current I1 and the voltage U1. In other embodiments, a plurality of second output units 130 may be arranged in parallel, each fed by the first monitoring element 110 with the current I1 and the voltage U1. Additionally or alternatively, a plurality of first output units 180 may be arranged in parallel, each fed by the first monitoring element 110 with the current I1 and the voltage U1.

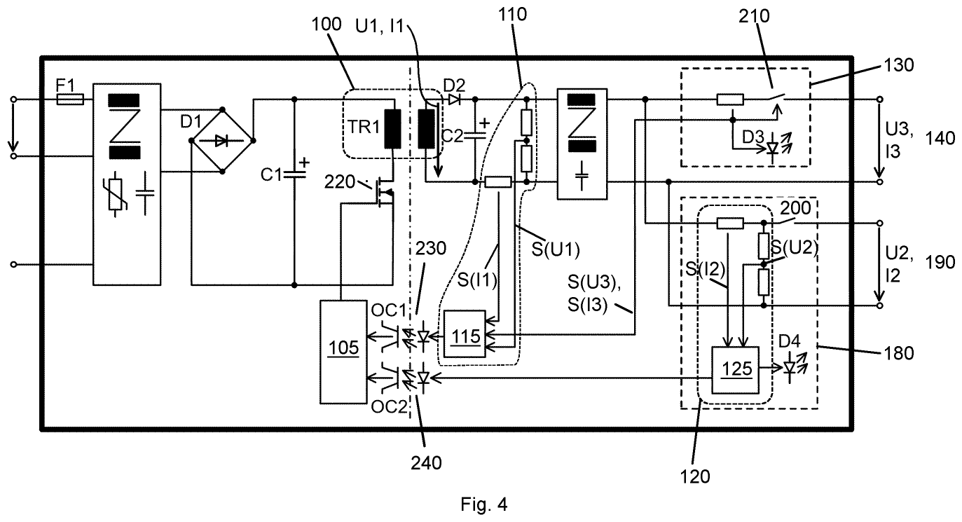

FIG. 4 shows a power supply 10 with a device 20 for its monitoring with a first output unit 180 and a second output unit 130. The first output unit 180 comprises a first switch 200 for shutting off the first supply output 190. The first switch 200 is controlled by the second monitoring element 120 and interrupts the provision of the second current I2 and the second voltage U2 in case of exceedance of the second threshold value. Furthermore, the second monitoring element 120 comprises the voltage divider for determining the signal S(U2) and the current measuring device implemented as a shunt resistor for determining the signal S(I2). The second monitoring element 120 also comprises the second comparator 125. The first output unit 180 comprises an indicator for signaling a threshold value exceedance in the form of a light-emitting diode (LED) D4, which is controlled by the second comparator 125.

Furthermore, the power supply 10 with the device 20 comprises the electrical components of the primary side known from FIG. 2, particularly the EMC filter, the rectifier D1, the capacitor C1, the partial voltage converter 100 of the primary side, the primary side control element 105, the switching element 220, and the primary side portions of the optocouplers OC1 and OC2. On the secondary side, the power supply 10 with the device 20 shows, similar to FIG. 2, the partial voltage converter 100 of the secondary side, the diode D2, the capacitor C2, the EMC filter (without reference number) at the output of the first monitoring element 110, and the secondary side portions of the optocouplers OC1 and OC2. The connection of the components largely corresponds to those in FIG. 2.

The second output unit 130 provides a third current I3 and a third voltage U3 at a second supply output 140. The second output unit 130 is supplied by the first monitoring element 110 with the first current I1 and the first voltage U1.

The second output unit 130 comprises a second switch 210 for shutting off the second supply output 140. The second switch 210 is controlled by the second output unit 130 and interrupts the provision of the third current I3 and the third voltage U3 in case of exceedance of the third threshold value. Optionally, the second output unit 130 may comprise a voltage divider for determining the signal S(U3), based on the voltage U3. Further optionally, the second output unit 130 may comprise a current measuring device, implemented as a shunt resistor, for determining the signal S(I3). The second output unit 130 also comprises an indicator for signaling a threshold value exceedance in the form of an LED D3, which is controlled by the second output unit 130. Further optionally, the second output unit 130 may electrically transmit the signals S(U3) and S(I3) to the first comparator 115 of the first monitoring element 110 via a connection line.

The first switch 200 is operated depending on an exceedance of the second threshold value. Signaling of the second threshold value is optionally based on a malfunction of the first switch 200. This may be coupled with signaling the exceedance of the second threshold value or signaled separately. The signaling may comprise details of the exceedance of the second threshold value as well as information about the first switch 200 and its function, e.g., malfunction, and state (open, closed). Separation of the first switch 200 is based on internal signals of the first output unit 180.

The second switch 210 is operated depending on an exceedance of a third threshold value. Separation of the second switch 210 is based on internal signals of the second output unit 130. Optionally, signaling of the exceedance of the third threshold value may be based on a malfunction of the second switch 210. Further optionally, the second switch 210 may be controlled by the first comparator 115.

As in FIG. 2, a primary side arranged switching element 220 is arranged between the primary side control element 105 and the voltage converter 100 and electrically connected with them. The switching element 220 controls the voltage converter 100 on the primary side based on signals from the primary side control element 105. The control influences the first current I1 and the first voltage U1. Alternatively, the control causes the shutdown of the first current I1 and the shutdown of the first voltage U1.

The signal conducting connection with the primary side control element 105 comprises an optical coupling element 230, 240. Alternatively, the coupling element 230, 240 may also comprise an inductive and/or a capacitive coupling. Optionally, the signal conducting connection with the first monitoring element 110 may comprise a first coupling element 230, and the signal conducting connection with the second monitoring element 120 may comprise a second coupling element 240. The first coupling element 230 and the second coupling element 240 may be arranged in parallel.

The monitoring elements 110, 120 are configured to monitor an exceedance of the threshold values as well as the duration of the threshold value exceedance. Signaling of the threshold value exceedance may take place only after the expiration of the predetermined duration. The duration may be selectable.

The threshold values may be adjustable by a user. This comprises the adjustability of the current upper limits I1′, I2′, I3′, the voltage upper limits U1′, U2′, U3′, and the power upper limits P1′, P2′, and P3′. This may also optionally comprise an individually adjustable duration of the respective threshold value exceedance.

The power supply 10 complies with the requirements for Safety Extra Low Voltage (SELV).

The voltage converter 100 of the power supply 10 may comprise a transformer, a switch mode power supply, a forward or flyback converter, or a resonant converter.

In other words, the invention may be summarized as follows: In an SELV Safety Extra Low Voltage power supply system with a DC voltage <60 volts (direct current) of, for example, 12 volts or 24 volts DC, to increase safety, the output power is limited according to UL 1310 (Class II Power Unit) to consistently less than 100 watts. Furthermore, the associated limitation mechanisms, such as voltage, current, and power limitation, must be implemented in a fault-tolerant redundant manner and thus doubled.

Systems oriented towards safety also require heightened protection against overvoltage and overcurrent. It is considered that the highest voltage in a power supply system determines the system voltage, and components may only operate safely up to a maximum voltage limit. Exceeding a current limit may cause a failure in a consumer connected to the system.

This limitation has a significant impact on the connected components and the installation. In non-redundantly power-limited power supplies, significant safety reserves must be considered, for example, in the wiring, and/or they may only be installed by professionals.

This redundant power limitation is achieved in the prior art by small power supplies that do not allow a power throughput of 100 watts. The first power limitation comprises of the natural power limitation of a power supply, which results from the maximum power limitation of the transformer 100. The second current limitation comprises of the usual built-in current limitation. Both mechanisms limit the maximum power in a fault-tolerant manner to a certain upper limit. However, due to considerable inaccuracy of the limitations, this requires a significant margin from the maximum possible output power. Additionally, downstream fuses at an output of the power supply 10 require a significant safety margin, as they allow a considerably higher current for a certain time than the nominal value of the fuse, which also strongly depends on the ambient temperature. In summary, these methods usually allow a limitation to a maximum of two-thirds of the maximum possible output power. To significantly approach the power limit, embodiments enable power supplies that redundantly implement the two voltage and current regulation (or voltage and current limitation).

The previously shown solutions of the prior art have the disadvantage that they either require a significant safety margin from the maximum output power or are realized with increased costs due to redundant regulations and/or limitations. Furthermore, the power limitation is only realized in power supplies that only have this power limitation.

A solution is presented for a flexibly redundant power-limited power supply, which has both one or more redundantly limited outputs 190 and one or more non-redundantly simply limited outputs 140.

In the inventive power supply 10, the output voltage U1 is regulated, and the current of an output I1 is simply detected and limited. Subsequently, any number of modules 180 follow, which have additional voltage and current regulation/limitation 120 with a voltage-current regulator/limiter for U2 and I2. These modules 180 also independently measure the output voltage and output current and report the respective output voltage and output current to the upstream power supply 110. Additionally, the total output current of all unsecured outputs 140 for I3 is detected. The power supply 10 calculates the current through each individual redundantly limited output from the total current I1 minus the current I3 of all unsecured outputs and the current I2 as well as possibly other redundantly limited outputs. If the output current of a redundantly secured output exceeds the limit, the limitation in the module 180 shuts it off as the first mechanism. For redundancy, the power supply 10 may also stop supplying this output and thereby shut it off or additionally shut off all output voltages U2 and U3.

The total shutdown of the power supply 10 plays a role, especially when, for example, the redundantly secured output 190 supplies sensors via wiring with the then allowed small cross-section. If these sensors fail, it is advantageous to shut down the entire system to prevent, for example, unmonitored operation of the connected consumer.

The modules 180 for voltage and current regulation (or limitation) may be supplied via another connection independent of the measured output current of the power supply or also from the measured output current. In the latter case, either the current consumption of the limitation modules 180 is considered in the calculation or may be neglected if it is significantly lower than the limitation.

This makes it possible to realize a modular power supply system that provides a significantly higher total output power and also enables redundantly fault-tolerant secure outputs 180 for wiring with small cross-sections. The presented power supply system may be realized, for example, in a power supply. The individual output channels may be realized with various switchable current limitations.

A power supply 10 comprises of the input and the simply voltage-and current-regulated output 140 shown here, as well as the redundantly regulated output 190. For this purpose, the power supply 10 has a primary side circuit part and a secondary side circuit part. The energy from the input side is transferred to the secondary side via a transformer TR1. The power supply may be designed both as a galvanically isolated switch mode power supply with galvanic isolation and non-galvanically isolated. The voltage and current regulation U1 and I1 of the power supply 10 detect the secondary side output quantities and report errors back to the primary side via the optocoupler OC1, where the primary side power path is controlled accordingly. However, the regulation of the first output quantities U1 and I1 may also be performed on the primary side, especially with a fixed input voltage. Furthermore, the described implementation is independent of the type of switch mode power supply. This may be realized in any way, for example, hard-switched as a forward or flyback converter or resonant switching, for example, as an LLC. Instead of inductive power transmission, capacitive transmission is also possible. The realization of the feedback is only intended to illustrate a principle; other methods, such as inductive feedback, are also possible. Also, the circuit breakers 200, 210 may be controlled on the primary or secondary side. What is decisive is only that there is a first regulation of the output quantities U1 and I1 for the simply regulated output 140.

In a first downstream module 130, the first outputs 140 of the switch mode power supply 10 are supplied from the secondary side power path as simply secured outputs 140. With another module 180, the outputs are monitored redundantly fault-tolerantly with the voltage and current limitation signals S(U2) and S(I2). If one of these signals S(U2) or S(I2) reports an exceedance of the limit value, at least the output 190 is shut off via switch S1. Likewise, the entire power supply 10 is shut down in this error case, or another switch before the output module 180 shuts it off. If the calculation of the total current I1 minus the current through one or more unsecured outputs I3 results in an exceedance of the redundantly fault-tolerant secure output current, switch S1 is also opened, and the redundantly regulated output 190 is shut off.

The output side modules 180 and/or 130 may be built-in or designed as plug-in modules. They may also independently signal the compliance with the current to the user through LEDs D3 and D4. Furthermore, the respective output may independently be shut off when the output current is exceeded. The configuration of the outputs may also be preset or adjustable via switches or an interface.

What is important here are the two types of outputs 190 and 140 in a power supply. The simply secured outputs 140 comprise of simple monitoring and/or control (e.g., regulation) of the output voltage and output current U3 and I3. In contrast, the fault-tolerant secure outputs 190 each have a fully redundant monitoring and/or control (e.g., regulation) with two separate voltage and current measurements U1 and U2 or I1 and I2, separate controls (e.g., regulations), and separate feedbacks OC1 and OC2, as well as optionally separate intervention options on the primary side.

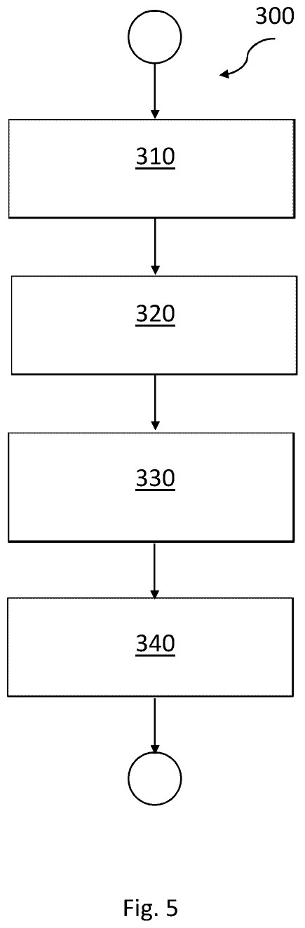

FIG. 5 illustrates a method 300 for monitoring a power supply for Safety Extra Low Voltage. The method comprises monitoring 310, with a first monitoring element, a first current I1, and a first voltage U1, which are output on the secondary side of a voltage converter. The method further comprises primary side controlling 320 of the voltage converter with a primary side control element, which is signal conducting connected to the first monitoring element, based on the first current I1 and the first voltage U1, when a first threshold value is exceeded. The method further comprises monitoring 330, with a second monitoring element, a second current I2, and a second voltage U2, wherein the second current I2 and the second voltage U2 are based on the first current I1 and the first voltage U1. The second monitoring element is supplied by the first monitoring element with the first current I1 and the first voltage U1. Furthermore, the method comprises primary side controlling 340 of the voltage converter based on the second current I2 and the second voltage U2, when a second threshold value is exceeded, wherein the primary side control element is signal conducting connected to the second monitoring element.

The method 300 for regulating a switch mode power supply with at least two output voltages may comprise a first regulation that generates a first output voltage U1, I1, and is output as a third output voltage U3, I3, and a second output voltage U2, I2, which is supplied from the first output voltage U1, I1, and output as a second output voltage U2, I2.

The output current I3 of the third output voltage U3, I3, is subtracted from the total output current I1 as the first calculated output current of the second output voltage U2, I2, and feedback as the first signal to the primary side. The second output voltage U2, I2, comprises its own independent second regulation, which has a second independent feedback to the primary side and enables double fault-tolerant secure regulation of the second output voltage U2, I2.

In embodiments, the output voltage of the outputs U2 and U3 may be adjustable. In further embodiments, the output current for each output may be individually adjustable. The output power for each output may also be individually adjustable. Furthermore, a current or power increase up to a certain limit and for a maximum time may be individually adjustable for each output. Moreover, behavior in case of exceeding the limit values may be adjustable, wherein, in embodiments, the entire power supply may be shut off, or wherein the respective output exceeding the limit value may be shut off. Additionally, the setting of the limit values and/or the states of the outputs or signaling may be carried out both at the power supply and via an interface with a control. Furthermore, additional output voltages may be generated and regulated simply or doubly according to the described method.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### REFERENCE SIGNS

10 Power Supply
20 Device for Monitoring the Power Supply
100 Voltage Converter of an Input Voltage
105 Primary Side Control Element
110 First Monitoring Element for U1 and I1
115 First Comparator
120 Second Monitoring Element U2 and I2
125 Second Comparator
130 Second Output Unit
140 Second Supply Output
180 First Output Unit (e.g., Module)
190 First Supply Output
200 First Switch
210 Second Switch
220 Switching Element
230 First Coupling Element
240 Second Coupling Element
300 Method for Monitoring a Power Supply
310 Monitoring with First Monitoring Element
320 Primary Side Controlling with Primary Side Control Element
330 Monitoring with Second Monitoring Element
340 Primary Side Controlling of the Voltage Converter

1: A device for monitoring a power supply for Safety Extra Low Voltage, comprising:
a first monitoring element configured to monitor a first current, I1, and a first voltage, U1, which are output on a secondary side of a voltage converter;
a primary side control element signal conducting connected to the first monitoring element and configured to control the voltage converter on a primary side based on the first current, I1, and the first voltage, U1, when a first threshold value is exceeded; and
a second monitoring element configured to monitor a second current, I2, and a second voltage, U2, the second current, I2, and the second voltage, U2, being based on the first current, I1, and the first voltage, U1, with the second monitoring element supplied by the first monitoring element with the first current, I1, and the first voltage, U1,
wherein the primary side control element is signal conducting connected to the second monitoring element and configured to control the voltage converter on the primary side based on the second current, I2, and the second voltage, U2, when a second threshold value is exceeded.

2: The device for monitoring the power supply of claim 1, wherein the first threshold value comprises a first current upper limit, I1′, and a first voltage upper limit, U1′, or a first power upper limit, P1′,
wherein the second threshold value comprises a second current upper limit, I2′, and a second voltage upper limit, U2′, or a second power upper limit, P2′,
wherein the first current upper limit, I1′, is equal to or greater than the second current upper limit, I2′, and
wherein the first voltage upper limit, U1′, or the first power upper limit, P1′, is equal to or greater than the second voltage upper limit, U2′, or the second power upper limit, P2′.

3: The device for monitoring the power supply of claim 1, further comprising:
a first output unit that provides the second current, I2, and the second voltage, U2, at a first supply output,
wherein the first output unit comprises the second monitoring element.

4: The device for monitoring the power supply of claim 3, wherein the first output unit comprises a first switch configured to shut off the first supply output.

5: The device for monitoring the power supply of claim 1, further comprising:
a second output unit that provides a third current, I3, and a third voltage, U3, at a second supply output,
wherein the second output unit is supplied by the first monitoring element with the first current, I1, and the first voltage, U1.

6: The device for monitoring the power supply of claim 5,
wherein the second output unit comprises a second switch configured to shut off the second supply output.

7: The device of claim 4,
wherein the first switch is operated depending on an exceedance of the second threshold value, and/or
wherein the second switch is operated depending on an exceedance of a third threshold value, and/or
wherein signaling of the second threshold value is based on a malfunction of the first switch.

8: The device of claim 7,
wherein separation of the second switch is based on internal signals of the second output unit, and/or
wherein separation of the first switch is based on internal signals of the first output unit.

9: The device of claim 1,
wherein a primary side arranged switching element is arranged between the primary side control element and the voltage converter and electrically connected with them,
wherein the switching element is configured to control the voltage converter on the primary side based on signals from the primary side control element, and
wherein the control causes an influence on the first current, I1, and the first voltage, U1, or wherein the control causes a shutdown of the first current, I1, and a shutdown of the first voltage, U1.

10: The device for monitoring the power supply of claim 1,
wherein the signal conducting connection with the primary side control element comprises an inductive and/or capacitive and/or optical coupling element.

11: The device for monitoring the power supply of claim 1,
wherein the monitoring elements are configured to monitor an exceedance of the threshold values and a duration of the threshold value exceedance, and
wherein signaling of the threshold value exceedance takes place only after an expiration of a predetermined duration.

12: The device for monitoring the power supply of claim 1,
wherein the threshold values are adjustable by a user, and/or
wherein the setting of the threshold values comprises an individually adjustable duration of the threshold value exceedance.

13: A power supply for Safety Extra Low Voltage, wherein the power supply meets requirements for Safety Extra Low Voltage, SELV, of claim 1.

14: The power supply for Safety Extra Low Voltage of claim 13,
wherein the voltage converter comprises a transformer or a switch mode power supply or a forward or flyback converter or a resonant converter.

15: A method for monitoring a power supply for Safety Extra Low Voltage, comprising:
monitoring, with a first monitoring element a first current, I1, and a first voltage, U1, which are output on a secondary side of a voltage converter;
primary side controlling of the voltage converter with a primary side control element, which is signal conducting connected to the first monitoring element, based on the first current, I1, and the first voltage, U1, when a first threshold value is exceeded,
monitoring, with a second monitoring element, a second current, I2, and a second voltage, U2, the second current, I2, and the second voltage, U2, being based on the first current, I1, and the first voltage, U1, with the second monitoring element supplied by the first monitoring element with the first current, I1, and the first voltage, U1; and
primary side controlling of the voltage converter based on the second current, I2, and the second voltage, U2, when a second threshold value is exceeded,
wherein the primary side control element is signal conducting connected to the second monitoring element

16: The device of claim 7, wherein signaling of the third threshold value is based on a malfunction of the second switch.

17: The device for monitoring the power supply of claim 10, wherein the signal conducting connection with the first monitoring element comprises a first coupling element and the signal conducting connection with the second monitoring element comprises a second coupling element.
